(19) United States
(12) Patent Application Publication
(10) Pub. No.: US 2004/0002213 A1
(43) Pub. Date: Jan. 1, 2004

(54) Method for descreasing number of particles during etching process

(76) Inventor: Chun-Ling Peng, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,766

(22) Filed: Aug. 15, 2002

(30) Foreign Application Priority Data
Jul. 1, 2002 (TW) 91114490

(51) Int. Cl. H01L 21/00; H01L 21/302; H01L 21/461

(52) U.S. Cl. 438/689

(57) ABSTRACT

A method for decreasing a number of particles during an etching process of a material layer is described, in which a wafer is put on a susceptor in an etching chamber. A series of etching tests are conducted at first under the same conditions as in the etching process but with various susceptor heights, and the obtained data is analyzed to find an optimum height that results in a minimum deviation of etching depth. A normal etching process is then performed to the wafer with the height of the susceptor being adjusted to the optimum one to improve the uniformity of etching rate.

### CROSS-REFERENCE TO RELATED INVENTION

This application claims the priority benefit of Taiwan application Ser. No. 91114490, filed Jul. 01, 2002.

### BACKGROUND OF THE INVENTION

1. Field of Invention

The present invention relates to an etching process in a semiconductor process. More particularly, the present invention relates to a method for decreasing the number of particles during an etching process.

2. Description of Related Art

In semiconductor processes, two types of etching mechanisms including wet etching and dry etching are widely used, while the latter has become the mainstream. The dry etching method features with using plasma for etching. In a dry etching process, a wafer is loaded in an etching chamber and the condition parameters of the etching process are adjusted according to the material to be etched and the thickness to be removed. Plasma is generated in the etching chamber to etch the wafer surface with bombardments and/or chemical effects of the active species in the plasma. Meanwhile, some material removed by bombardments of the active species forms solid etching by-products and adheres to the inner wall of the etching chamber.

When the etching rate is not uniform over the whole wafer, the solid etching by-products do not distribute evenly on the chamber wall. The regions of the chamber wall corresponding to the wafer regions having higher etching rates are deposited with more solid etching by-products, so particles are easily generated therefrom. Consequently, the frequency of periodic maintenance must be increased and the throughput is lowered.

### SUMMARY OF THE INVENTION

Accordingly, this invention provides a method for decreasing a number of particles during an etching process of a material layer.

This invention also aims to decrease the frequency of periodic maintenance and increase the throughput by providing a method for decreasing the number of particles during an etching process.

This invention further provides an etching process for etching a material layer on a substrate, which generates less particles and therefore is capable of decreasing the frequency of periodic maintenance to increase the throughput.

In a method for decreasing the number of particles during an etching process of this invention, the etching process is performed in an etching chamber and the target wafer is put on a susceptor in the etching chamber. At first, a series of etching tests are conducted under the same conditions as in the etching process but with various susceptor heights, and the obtained data is analyzed to find an optimum height that results in a minimum deviation of etching depth. A normal etching process is then performed to the wafer with the height of the susceptor being adjusted to the optimum one to improve the uniformity of etching rate.

In an etching process for etching a material layer on a substrate of this invention, a substrate is loaded on a susceptor in an etching chamber. The etching process is performed with the height of the susceptor in the etching chamber being adjusted to an optimum one that results in a minimum deviation of etching depth of the material layer in the etching process. The height of the substrate can be adjusted with a shaft under the susceptor capable of moving up and down to drive the susceptor vertically, and the material layer comprises, for example, silicon oxide.

As mentioned above, in this invention, a series of etching tests are conducted at first to obtain an optimum height that results in a minimum deviation of etching depth, and then the normal etching process is performed with the height of the susceptor being set to the optimum height. Since a minimum deviation of etching depth corresponds to a minimum deviation of etching rate, the solid etching byproducts distribute more evenly on the inner wall of the etching chamber. Consequently, fewer particles are generated, and the yield therefore can be increased. Meanwhile, the frequency of periodic maintenance can be lowered to increase the throughput of the semiconductor process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a method for decreasing the number of particles during an etching process according to a preferred embodiment of this invention;

FIG. 2 illustrates a locally enlarged view of a first example of the etching process illustrated in FIG. 1;

FIG. 3 shows the correlation between the number of particles, the etching rate and the standard deviation of the etching depths in the first example;

FIG. 4 plots the results of the first example and the prior art for comparison; and

FIG. 5 illustrates a locally enlarged view of a second example of the etching process illustrated in FIG. 1;

### DETAILED DESCRIPTION

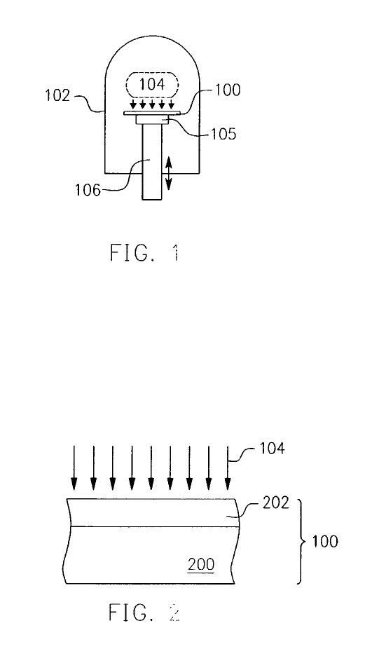

FIG. 1 illustrates a method for decreasing the number of particles during an etching process according to the preferred embodiment of this invention

Refer to FIG. 1, a wafer 100 is loaded on a susceptor 105 in an etching chamber 102. Then, an etching process is performed by using plasma 104 with the height of the susceptor 105 in the etching chamber being adjusted to an optimum height that results in a minimum deviation of etching depth to improve the uniformity of the etching rates over the whole wafer 100. The optimum height is obtained by performing a series of etching tests under the same conditions as in the etching process but with various susceptor heights, and then analyzing the obtained data to find the height results in a minimum deviation of etching depth. The height of the susceptor 105 can be adjusted vertically by using a shaft 106 under the susceptor 105 capable of moving up and down. A first example is illustrated in FIG. 2 and is described below to further explain this invention.

### EXAMPLE 1

FIG. 2 illustrates a locally enlarged view of the first example of the etching process illustrated in FIG. 1.

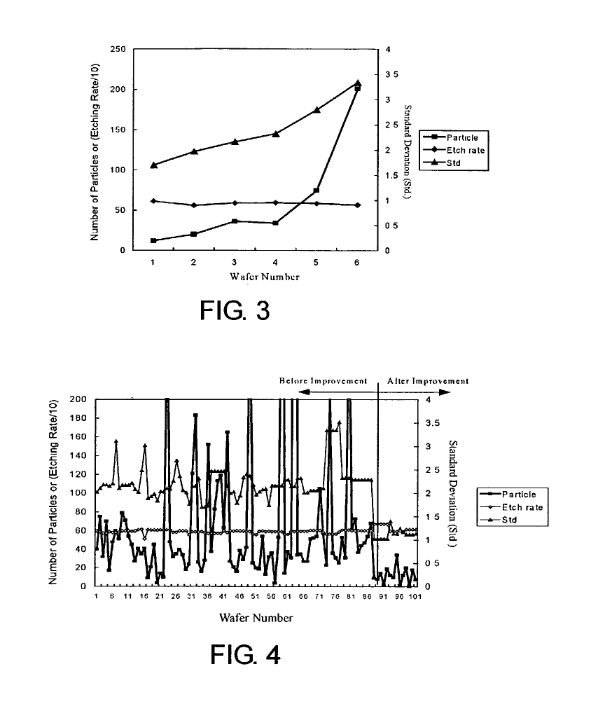

Refer to FIG. 2, the wafer 100 comprises a substrate 200 and a silicon oxide layer 202 to be etched. Plasma 104 is generated to bombard (etch) the silicon oxide layer 202 to remove a thickness of 300˜800 Å. After the etching process, the wafer surface is analyzed for the number of particles, the etching rate and the etching depth variation. The above steps are repeated with various susceptor heights, and the results are shown in FIG. 3.

FIG. 3 shows the correlation between the number of particles, the etching rate and the standard deviation (Std.) of the etching depths in Example 1. The x-axis represents the wafer number, the left y-axis represents the number of particles and the etching rate (/10) and the right y-axis represents the standard deviation (Std.) of the etching depths.

As shown in FIG. 3, the etching rate is substantially constant. When the standard deviation of the etching depths is smaller, which means the etching rate of the material layer on the wafer is more uniform, the number of the particles coming from the solid etching by-products on the chamber wall decreases.

FIG. 4 plots the results of the first example and the prior art for comparison, wherein the x-axis represents the wafer number, the left y-axis represents the number of particles and the etching rate (/10) and the right y-axis represents the standard deviation (Std.) of the etching depths.

Refer to FIG. 4, the data points (number of particles, etching rate and standard deviation of etching depths) in the region labeled with “after improvement” are the results of this invention and those in the region labeled with “before improvement” are the results of the prior art. It is quite obvious that using the method of this invention can greatly decrease the number of particles.

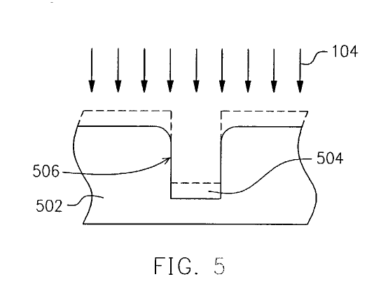

Moreover, except the etching process described in Example 1, the invention can be applied to a corner-rounding etching process. Such a process is conducted to round the corners of openings in a dielectric layer, as shown in FIG. 5.

### EXAMPLE 2

FIG. 5 illustrates a locally enlarged view of the second example of the etching process illustrated in FIG. 1.

Refer to FIG. 5, the layer to be etched is a dielectric layer 502 that has an opening 504 therein. The dielectric layer 502 comprises a material such as silicon oxide. In the etching process for rounding the corners of the opening 504, the wafer is loaded on a susceptor in the etching chamber (not shown), and the height of the susceptor is adjusted to an optimum one that results in a minimum deviation of etching depth of the dielectric layer 502. In addition, the height of the substrate can be adjusted with a shaft (not shown) under the susceptor capable of moving up and down to drive the susceptor vertically. Then, plasma 104 is generated to bombard the dielectric layer 502 with chemically active species to round the top corner 506 of the opening 504 and remove a top portion of the dielectric layer 502 at the same time. The optimum height is obtained by performing a series of etching tests with the same conditions as in the corner-rounding etching process but with various susceptor heights, and then analyzing the obtained data to find the height results in a minimum deviation of etching depth.

As mentioned above, this invention conducts a series of etching tests to obtain an optimum height that results in a minimum deviation of etching depth, and then performing the normal etching process with the height of the susceptor being set to the optimum one. Since a minimum deviation of etching depth corresponds to a minimum deviation of etching rate, the solid etching by-products distribute more evenly on the inner wall of the etching chamber. Consequently, fewer particles are generated, and the yield therefore can be increased. Meanwhile, the frequency of periodic maintenance can be lowered to increase the throughput of the semiconductor process.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method for decreasing a number of particles during an etching process of a material layer in which a wafer is put on a susceptor in an etching chamber, comprising:
setting a height of the susceptor and performing an etching process at such a height;
measuring deviations of etching depth at different locations under such a height;
repeating the above two steps with respect to various heights so as to obtain several sets of corresponding data for different heights; and
selecting the height resulting in a minimum deviation of etching depth as a height to perform a normal etching process.

2. The method of claim 1, wherein the height of the wafer is adjusted with a shaft under the susceptor, the shaft being capable of moving up and down to drive the susceptor vertically.

3. The method of claim 1, wherein the material layer comprises silicon oxide.

4. The method of claim 1, wherein the material layer is a dielectric layer, the etching chamber is a part of a metal deposition machine, and the etching process is for rounding a corner of an opening in the dielectric layer.

5. An etching process for etching a material layer on a substrate, comprising:
loading the substrate on a susceptor in an etching chamber used for the etching process; and
performing the etching process with a height of the susceptor in the etching chamber being adjusted to an optimum height that results in a minimum deviation of etching depth of the material layer in the etching process.

6. The etching process of claim 5, wherein the height of the substrate is adjusted with a shaft under the susceptor, the shaft being capable of moving up and down to drive the susceptor vertically.

7. The etching process of claim 5, wherein the material layer comprises a silicon oxide layer.

8. A method for rounding a corner of an opening in a dielectric layer on a substrate, comprising:
loading the substrate on a susceptor in an etching chamber; and
performing a corner-rounding etching process to round the corner of the opening in the dielectric layer with a height of the substrate in the etching chamber being adjusted to an optimum height that results in a minimum deviation of etching depth of the dielectric layer in the corner-rounding etching process.

9. The method of claim 8, wherein the height of the substrate is adjusted with a shaft under the susceptor, the shaft being capable of moving up and down to drive the susceptor vertically.

10. The method of claim 8, wherein the dielectric layer comprises silicon oxide.
